(19) United States
(12) Patent Application Publication
(10) Pub. No.: US 2024/0033785 A1
(43) Pub. Date: Feb. 1, 2024

(54) Convenient cleaning apparatus and cleaning method for industrial control computer

(71) Applicant: ADVANTECH TECHNOLOGY (CHINA) CO., LTD., Kunshan City, Jiangsu (CN)

(72) Inventor: Yongzheng HUANG, Kunshan City, Jiangsu (CN)

(21) Appl. No.: 17/610,166

(22) PCT Filed: Aug. 31, 2021
(86) PCT No.: PCT/CN2021/115713

§ 371 Date: Jan. 12, 2023

(30) Foreign Application Priority Data
Jul. 7, 2021 (CN) 202110767398.1

(51) Int. Cl. B08B 1/04; B08B 1/00; B08B 5/02

(52) U.S. Cl. CPC B08B 1/04; B08B 1/002; B08B 5/02; B08B 2205/00

(57) ABSTRACT

The disclosure discloses a convenient cleaning apparatus and cleaning method for an industrial control computer, including an industrial control computer body (1), and a heat dissipation hole is formed in a front side wall of the industrial control computer body (1), and a heat dissipation net (2) is arranged in the heat dissipation hole; a first cleaning device is arranged inside the industrial control computer body (1), and the first cleaning device is configured to clean the heat dissipation net (2); a plurality of heat dissipation fins (3) are arranged on an outer wall of an upper end of the industrial control computer body (1); and a second cleaning device is arranged outside the industrial control computer body (1), and the second cleaning device is configured to clean the heat dissipation fins (3). In the disclosure, by providing the first cleaning device and second cleaning device, cleaning of the heat dissipation net and the heat dissipation fins can be completed, which reduces the dust attached to the surfaces of the heat dissipation net and the heat dissipation fins to achieve high efficient heat dissipation. In addition, there is no need for a worker to clean, which reduces labor intensity of the worker, and also improves safety of cleaning for the industrial control computer body.

### CROSS-REFERENCE TO RELATED APPLICATION

The disclosure claims the priority of a Chinese Patent Application No. 202110767398.1, entitled “CONVENIENT CLEANING APPARATUS AND CLEANING METHOD FOR INDUSTRIAL CONTROL COMPUTER”, and filed on Jul. 7, 2021, the entire contents of which are incorporated herein by reference.

### TECHNICAL FIELD

The disclosure relates to a field of cleaning technology of an industrial control computer, and in particular to a convenient cleaning apparatus and cleaning method for an industrial control computer.

### BACKGROUND OF THE INVENTION

An industrial control computer is a host that has been widely applied in industry, not only requires it stable in performance, more importantly, the industrial control computer should be good in heat dissipation performance. In order to improve a heat dissipation effect of the industrial control computer, the existing industrial control computer usually adopts a heat dissipation approach, such as arranging a heat dissipation fan internally or arranging heat dissipation fins on an outer wall thereof, to dissipate heat. However, plenty of dusty is in the existing application scenes of the industrial control computer, so that a lot of dust is attached to a heat dissipation net of the industrial control computer or the heat dissipation fins outside the industrial control computer, which results in blocking of the heat dissipation net and the heat dissipation performance of the heat dissipation fins is reduced, and the heat dissipation effect of the industrial control computer is seriously affected. Besides, workers might be scratched by the heat dissipation fins during cleaning, leading to possible production accidents.

### SUMMARY OF THE INVENTION

A convenient cleaning apparatus and a cleaning method for an industrial control computer according to embodiments of the disclosure are provided to solve the technical problems that plenty of dusty is in the existing application scenes of the industrial control computer, and a lot of dust is attached to a heat dissipation net of the industrial control computer or the heat dissipation fins outside the industrial control computer, which results in blocking of the heat dissipation net and the heat dissipation performance of the heat dissipation fins is reduced, and the heat dissipation effect of the industrial control computer is seriously affected; in addition, workers might be scratched by the heat dissipation fins during cleaning, leading to possible production accidents.

In a first aspect, one or more embodiments of the disclosure disclose a convenient cleaning apparatus for an industrial control computer, including: an industrial control computer body, and a heat dissipation hole is formed in a front side wall of the industrial control computer body, and a heat dissipation net is arranged in the heat dissipation hole; a first cleaning device is arranged inside the industrial control computer body, and the first cleaning device is configured to clean the heat dissipation net; a plurality of heat dissipation fins are arranged on an outer wall of an upper end of the industrial control computer body; and a second cleaning device is arranged outside the industrial control computer body, and the second cleaning device is configured to clean the heat dissipation fins.

In some embodiments, the plurality of heat dissipation fins are arranged at equal intervals, and the plurality of heat dissipation fins are parallel to each other.

In some embodiments, the first cleaning device includes:
a first motor, arranged inside the industrial control computer body, and an upper end of the first motor is fixedly connected to an inner wall of the upper end of the industrial control computer body, and the first motor is a forward/reverse rotation motor;
a first screw rod, an end of the first screw rod is fixedly connected to an output end of the first motor, and another end of the first screw rod is rotatably connected to an inner wall of a lower end of the industrial control computer body;
a first sliding block, arranged on the first screw rod, and a threaded hole is formed in the first sliding block in a penetrating manner, and the first sliding block is in threaded driving connection with the first screw rod via the threaded hole, and a first through hole is further formed in the first sliding block, and the first through hole passes through an upper surface and a lower surface of the first sliding block;
a guide rod, arranged between the first motor and the heat dissipation net, and an upper end and a lower end of the guide rod are fixedly connected to inner walls of an upper side and a lower side of the industrial control computer body respectively, and the guide rod is slidably connected with an inner wall of the first through hole, and the first sliding block slides up and down along the guide rod;
a first bristles, arranged on a side of the first sliding block facing the heat dissipation net, and an end of the first bristles is fixedly connected to a side wall of the first sliding block, and another end of the first bristles is in contact with an inner side wall of the heat dissipation net.

In some embodiments, a second through hole is arranged below the heat dissipation net, and a first dust receiving box is arranged in the second through hole, and the first dust receiving box is configured in a drawer shape, and the first dust receiving box is slidably connected with an inner wall of the second through hole, and an upper end of the first dust receiving box is provided with an opening.

In some embodiments, a first air pipe is arranged at a front side of the heat dissipation net, and an end of the first air pipe is fixedly connected to a front side wall of the industrial control computer body, and the first air pipe is in communication with the heat dissipation hole, and an upper end of the first air pipe is provided with a plurality of second air pipes, and the second air pipes are configured in L shapes; an end of one of the second air pipes is in communication with an upper end of the first air pipe, and another end of one of the second air pipes is provided with a nozzle, and an outlet of the nozzle faces an upper surface of the industrial control computer body; and a plurality of intervals are formed between every two adjacent heat dissipation fins, and the plurality of intervals are in one-to-one correspondence with the plurality of the second air pipes.

In some embodiments, a heat dissipation fan is arranged in the industrial control computer body, and the heat dissipation fan directly faces the heat dissipation net and the heat dissipation fan is fixedly connected to an inner wall of a rear side of the industrial control computer body via a connecting pole.

In some embodiments, the second cleaning device includes:
a second motor, arranged on an outer wall of a left side of the industrial control computer body, and an output end of the second motor is provided with a first gear, and the first gear is an incomplete gear, and the output end of the second motor is fixedly connected to the first gear;
a first fixing plate, arranged on a left side wall of the industrial control computer body, and a third through hole is formed in the first fixing plate;
a second fixing plate, arranged on the left side wall of the industrial control computer body, and the second fixing plate is located in front of the first fixing plate, and a fourth through hole with a same size as the third through hole is formed in the second fixing plate;
a sliding plate, an end of the sliding plate is slidably connected with the first fixing plate via the third through hole, and another end of the sliding plate is slidably connected with the second fixing plate via the fourth through hole;
a rack, arranged on a left side of the sliding plate, and a side wall of the rack is fixedly connected with a side wall of the sliding plate, and both an upper end and a lower end of the rack have teeth, and a toothed position at the lower end of the rack is intermittently meshed with the first gear, and the rack 20 slides back and forth between the first fixed plate and the second fixed plate along with the sliding plate;
a baffle, arranged at a front end of the sliding plate;
a first spring, being sleeved on the sliding plate, and an end of the first spring 22 is fixedly connected to a rear side wall of the baffle, and another end of the first spring is fixedly connected to a front side wall of the second fixing plate;
a first rotating shaft, arranged on the left side wall of the industrial control computer body, and the first rotating shaft is perpendicular to the left side wall of the industrial control computer body and is rotatably connected to the left side wall of the industrial control computer body, and the first rotating shaft is located above the sliding plate, and an end, away from the industrial control computer body, of the first rotating shaft is provided with a second gear 24, and the second gear 24 is fixedly connected to the first rotating shaft, and a tooth profile of the second gear 24 meshes with a toothed position at the upper end of the rack; and
a connecting pole, arranged at a periphery of the second gear, and an end of the connecting pole is fixedly connected to an outer wall of the second gear, and another end of the connecting pole is provided with a mounting plate, and the connecting pole is hinged to a left side wall of the mounting plate, and a plurality of cleaning assemblies are arranged under the mounting plate, and the plurality of the cleaning assemblies are distributed between every two adjacent heat dissipation fins.

In some embodiments, each of the cleaning assemblies includes:
a second sliding block, arranged between two adjacent heat dissipation fins, and a left end and a right end of the second sliding block are symmetrically provided with a third sliding block, a side, facing the second sliding block, of each of the heat dissipation fins is provided with a sliding groove matched with the third sliding block, and the third sliding block is slidably connected with the sliding groove, and the second sliding block slides back and forth along a side wall of each of the heat dissipation fins;
a mounting pole, arranged on a lower surface of the second sliding block, and an upper end of the mounting pole is fixedly connected to the lower surface of the second sliding block, and an outer wall of the mounting pole is provided with a plurality of second bristles, and an end of the second bristles is fixedly connected to an outer wall of the mounting pole, and another end of the second bristles 31 is in contact with an outer wall of each of the heat dissipation fins; and
a sleeve, arranged at an upper end of the second sliding block, and a lower end of the sleeve is fixedly connected to the upper end of the second sliding block, and a second spring is arranged in the sleeve, and an end of the second spring is fixedly connected to an inner wall of the sleeve, and another end of the second spring is provided with a sliding rod, and an end of the sliding rod is slidably connected with the inner wall of the sleeve, and another end of the sliding rod extends above the sleeve and is fixedly connected to a lower surface of the mounting plate.

In some embodiments, a front side wall and a rear side wall of the industrial control computer body are symmetrically provided with dust receiving assemblies, and each of the dust receiving assemblies includes:
a second dust receiving box, an end of the second dust receiving box is provided with a first clamping plate, and another end of the second dust receiving box is provided with a second clamping plate, and a second threaded hole is formed in the second clamping plate, and a right side wall of the first clamping plate is in contact with the outer wall of the left side of the industrial control computer body; and
a second stud, being in threaded driving connection with the second clamping plate via the second threaded hole, and the second stud is perpendicular to the second clamping plate, and an end, close to a right side wall of the industrial control computer body, of the second stud is provided with an anti-skid plate, and the anti-skid plate is rotatably connected to an end of the second stud, and another end of the second stud extends to a right side of the second clamping plate and is provided with a knob, and the knob is fixedly connected to the second stud.

In a second aspect, one or more embodiments of the disclosure disclose a cleaning method of a convenient cleaning apparatus for an industrial control computer, using the convenient cleaning apparatus for an industrial control computer as claimed in claim 9 to clean an industrial control computer, wherein the cleaning method comprises the following steps:
step 1, actuating the first motor, the first motor rotates forwards to drive the first sliding block to slide downwards along the guide rod, and the first sliding block drives the first bristles to clean an inner wall of the heat dissipation net from top to bottom; when the first sliding block moves to a preset lowest position, the first motor reversely rotates to drive the first sliding block to slide upwards along the guide rod, and the first sliding block drives the first bristles to clean the inner wall of the heat dissipation net again from bottom to top; and when the first sliding block moves to a preset highest position, the first motor rotates forwards again, and repeating the above-mentioned operations;
step 2, actuating the second motor, the second motor rotates to drive the cleaning assemblies to slide back and forth on the upper surface of the industrial control computer body, and the second bristles cleans a side wall of one of the heat dissipation fins and the upper surface of the industrial control computer; and
step 3, after the heat dissipation net is cleaned up, turning off the first motor, and when the heat dissipation fins are cleaned up, turning off the second motor.

According to one or more embodiments of the disclosure, a convenient cleaning apparatus and cleaning method for an industrial control computer includes an industrial control computer body, and a heat dissipation hole is formed in a front side wall of the industrial control computer body, and a heat dissipation net is arranged in the heat dissipation hole; a first cleaning device is arranged inside the industrial control computer body, and the first cleaning device is configured to clean the heat dissipation net; a plurality of heat dissipation fins are arranged on an outer wall of an upper end of the industrial control computer body, and a second cleaning device is arranged outside the industrial control computer body, and the second cleaning device is configured to clean the heat dissipation fins. In the disclosure, by providing the first cleaning device and second cleaning device, cleaning of the heat dissipation net and the heat dissipation fins can be completed, which reduces the dust attached to the surfaces of the heat dissipation net and the heat dissipation fins to achieve high efficient heat dissipation. In addition, there is no need for a worker to clean, which reduces labor intensity of the worker, and also improves safety of cleaning for the industrial control computer body.

Other features and advantages of the disclosure will be described in the following detailed description, and will be partly obvious from the description or understood by implementing the disclosure. The objective and other advantages of the disclosure can be realized and obtained by means of the apparatus specifically illustrated in the description and the accompanying drawings of the description.

The technical solutions of the disclosure will be further described in detail below with reference to the accompanying drawings and embodiments.

### BRIEF DESCRIPTION OF THE DRAWINGS

The accompanying drawings are provided for a further understanding of the disclosure, which constitute a part of the specification for illustrating the disclosure together with the embodiments of the disclosure, but do not constitute a limitation to the disclosure. In the drawings:

FIG. 1 is a schematic diagram of an overall structure of a convenient cleaning apparatus for an industrial control computer according to some embodiments of the disclosure;

FIG. 2 is a left side view of an internal structure of a convenient cleaning apparatus for an industrial control computer according to some embodiments of the disclosure;

FIG. 3 is a left side view of a convenient cleaning apparatus for an industrial control computer according to some embodiments of the disclosure;

FIG. 4 is an enlarged view at A in FIG. 1 of the disclosure; and

FIG. 5 is a top view of a dust receiving assembly of a convenient cleaning apparatus for an industrial control computer according to some embodiments of the disclosure.

In the figures: 1. Industrial control computer body; 2. Heat dissipation net; 3. Heat dissipation fins; 4. First motor; 5. First screw rod; 6. First sliding block; 7. Guide rod; 8. First bristles; 9. First dust receiving box; 10. First air pipe; 11. Second air pipe; 12. Nozzle; 13. heat dissipation fan; 14. Connecting pole; 15. Second motor; 16. First gear; 17. First fixing plate; 18. Second fixing plate; 19. Sliding plate; 20. Rack; 21. Baffle; 22. First spring; 23. first rotating shaft; 24. Second gear; 25. connecting rod; 26. Mounting plate; 27. Second sliding block; 28. Third sliding block; 29. Sliding groove; 30. mounting pole; 31. Second bristles; 32. Sleeve; 33. Second spring; 34. Sliding rod; 35. Second dust receiving box; 36. First clamping plate; 37, Second clamping plate; 38, Second stud; 39. Anti-skid plate; 40. Knob.

### DETAILED DESCRIPTION OF THE INVENTION

The preferred embodiments of the disclosure will be described below with reference to the accompanying drawings. It should be understood that the preferred embodiments described herein are only used to illustrate and explain the disclosure, but not to limit the disclosure.

In addition, the descriptions of “first”, “second” and the like in the disclosure are for descriptive purposes only, and are not specifically intended to refer to a meaning of an order or sequence, and are not intended to limit the disclosure, and are merely used to distinguish the components or operations described in the same technical terms, but cannot be understood as indicating or implying relative importance or implicitly indicating the number of indicated technical features. Thus, features defined with “first” and “second” may explicitly or implicitly include at least one of the features. In addition, the technical solutions and technical features between various embodiments may be combined with each other, but must be implemented as a basis for a person of ordinary skill in the art, and when the combination of the technical solutions is contradictory or cannot be implemented, it should be considered that the combination of the technical solutions is not present, and is not within the protection scope of the disclosure.

### Embodiment 1

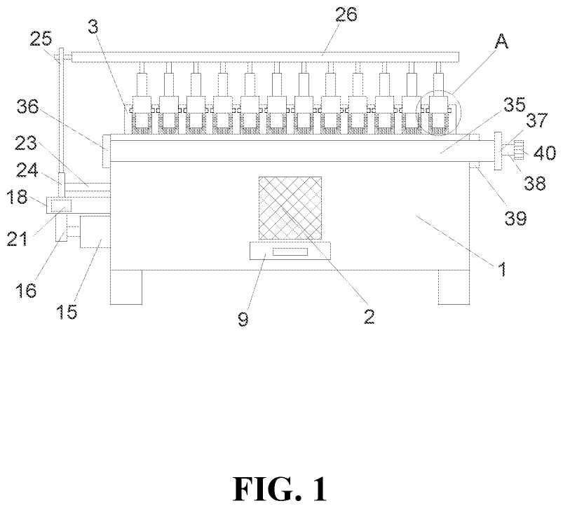

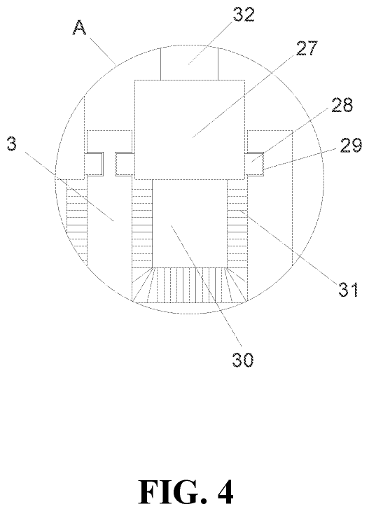

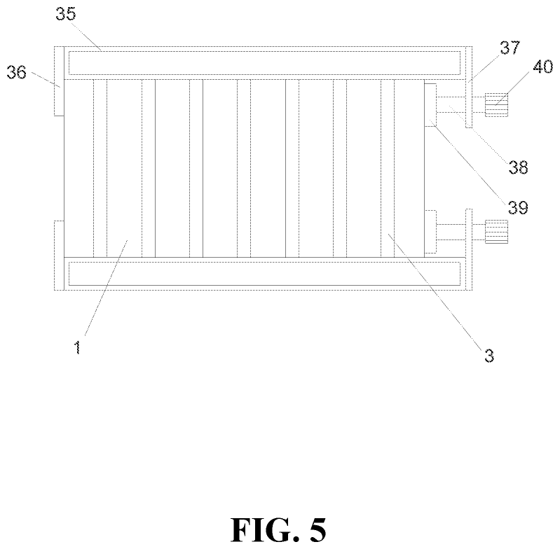

A convenient cleaning apparatus for an industrial control computer according to an embodiment of the disclosure, as shown in FIGS. 1-5, includes: an industrial control computer body 1, wherein a front side wall of the industrial control computer body 1 is provided with a heat dissipation hole, and a heat dissipation net 2 is arranged in the heat dissipation hole; a first cleaning device is provided in the industrial control computer body 1, and the first cleaning device is configured to clean the heat dissipation net 2; an outer wall of an upper end of the industrial control computer body 1 is provided with a plurality of heat dissipation fins 3; and a second cleaning device is provided outside the industrial control computer body 1, and the second cleaning device is configured to clean the heat dissipation fins 3.

A working principle and beneficial effects of the above-mentioned technical solution are as follows: in the disclosure, the first cleaning device is provided in the industrial control computer body 1, and the first cleaning device can clean up the heat dissipation net 2 arranged at the front side wall of the industrial control computer body 1 without disassembling the heat dissipation net 2, thereby improving service lives of the heat dissipation net 2 and the industrial control computer body 1. Through cleaning by the first cleaning device, dust inside the heat dissipation net 2 is reduced and the heat dissipation net 2 is prevented from being blocked, so that the interior of the industrial control computer body 1 is in communication with the outside, thereby improving heat dissipation effect. The second cleaning device is provided outside the industrial control computer body 1, and an upper surface of the industrial control computer body 1 and outer walls of the heat dissipation fins 3 can be cleaned up by means of the second cleaning device, so as to improve heat conduction efficiency and heat dissipation efficiency of the heat dissipation fins 3. Therefore, the heat dissipation effect of the industrial control computer body 1 is further improved. In the disclosure, by providing the first cleaning device and second cleaning device, cleaning of the heat dissipation net 2 and the heat dissipation fins 3 can be completed, which reduces the dust attached to the surfaces of the heat dissipation net 2 and the heat dissipation fins 3 to enable high efficient heat dissipation, and avoids manual cleaning by a worker to reduce labor intensity of the worker, and also improves safety of cleaning for the industrial control computer body 1, and the problem that the worker is scratched by the heat dissipation fins 3 during cleaning of the heat dissipation fins 3 is solved.

### Embodiment 2

On the basis of the above-mentioned embodiment 1, a plurality of heat dissipation fins 3 are arranged at equal intervals, and the plurality of heat dissipation fins 3 are parallel to each other.

A working principle and a beneficial effect of the above-mentioned technical solution are as follows: a plurality of heat dissipation fins 3 are arranged, and the plurality of heat dissipation fins 3 are distributed on the upper surface of the industrial control computer body 1 in an array, so as to significantly accelerate a heat dissipation speed of the industrial control computer body 1.

### Embodiment 3

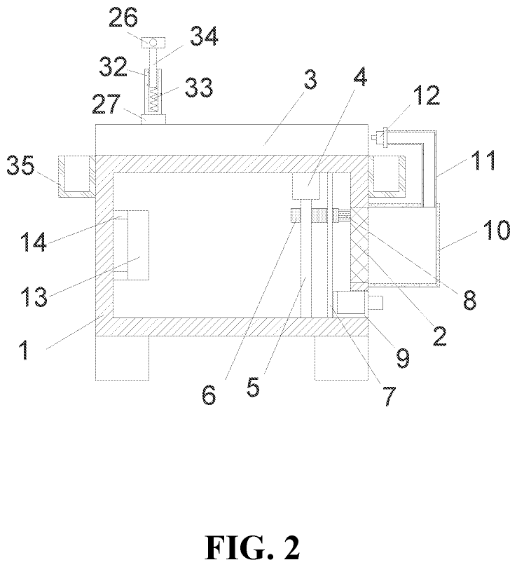

On the basis of embodiment 1 or 2, as shown in FIG. 2, the first cleaning device includes:
a first motor 4, arranged in the industrial control computer body 1, wherein an upper end of the first motor 4 is fixedly connected to an inner wall of the upper end of the industrial control computer body 1, and the first motor 4 is a forward/reverse rotation motor;
a first screw rod 5, an end of the first screw rod 5 is fixedly connected to an output end of the first motor 4, and another end of the first screw rod 5 is rotatably connected to an inner wall of a lower end of the industrial control computer body 1;
a first sliding block 6, arranged on the first screw rod 5, wherein a threaded hole is formed in the first sliding block 6 in a penetrating manner, and the first sliding block 6 is in threaded driving connection with the first screw rod 5 via the threaded hole, and a first through hole is further formed in the first sliding block 6, and the first through hole passes through an upper surface and a lower surface of the first sliding block 6;
a guide rod 7, arranged between the first motor 4 and the heat dissipation net 2, and an upper end and a lower end of the guide rod 7 are fixedly connected to inner walls of an upper side and a lower side of the industrial control computer body 1 respectively, and the guide rod 7 is slidably connected with an inner wall of the first through hole, and the first sliding block 6 slides up and down along the guide rod 7;
a first bristles 8, arranged on a side of the first sliding block 6 facing the heat dissipation net 2, and an end of the first bristles 8 is fixedly connected to a side wall of the first sliding block 6, and another end of the first bristles 8 is in contact with an inner side wall of the heat dissipation net 2; and
a second through hole is arranged below the heat dissipation net 2, wherein a first dust receiving box 9 is provided in the second through hole, and first dust receiving box 9 is configured in a drawer shape, and the first dust receiving box 9 is slidably connected with an inner wall of the second through hole, and an upper end of the first dust receiving box 9 is provided with an opening.

A working principle and beneficial effects of the above-mentioned technical solution are as follows: when the heat dissipation net 2 needs to be cleaned, the first motor 4 is actuated. A rotation of the first motor 4 can drive the first screw rod 5 to rotate, and the first screw rod 5 can drive, by threaded driving, the first sliding block 6 to move along the guide rod 7. The first motor 4 is a forward/reverse rotation motor, the first sliding block 6 can be driven to reciprocate up and down along the guide rod 7 through forward rotation and reverse rotation of the first motor 4, and the first bristles 8 can be driven to reciprocate up and down on the inner wall of the heat dissipating net 2. In this way, dust on the inner wall of the heat dissipating net 2 is cleaning up, the fallen dust falls into the first dust receiving box 9 which is in a drawer shape; and then the first dust receiving box 9 is regularly taken out from the second through hole to pour out the collected dust. Therefore, cleaning of the inner wall of the heat dissipation net 2 is realized, thereby keeping the heat dissipation net 2 unobstructed inside out and ensuring a heat dissipation speed.

### Embodiment 4

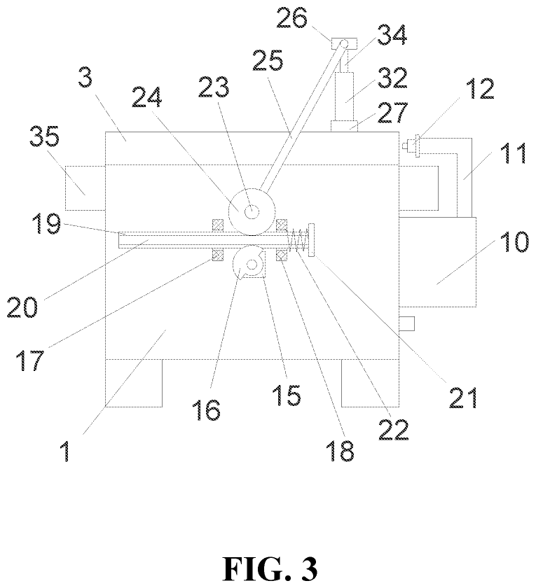

On the basis of embodiment 1, as shown in FIGS. 2 and 3, a first air pipe 10 is provided at a front side of the heat dissipation net 2, and an end of the first air pipe 10 is fixedly connected to a front side wall of the industrial control computer body 1. The first air pipe 10 is in communication with the heat dissipation hole, and an upper end of the first air pipe 10 is provided with a plurality of second air pipes 11, and the plurality of second air pipes 11 are configured in L shapes. An end of one of the second air pipes 11 is in communication with an upper end of the first air pipe 10, and another end of one of the second air pipes 11 is provided with a nozzle 12. An outlet of the nozzle 12 faces an upper surface of the industrial control computer body 1. A plurality of intervals are formed between every two adjacent heat dissipation fins 3, and the plurality of intervals are in one-to-one correspondence with the plurality of second air pipes 11.

A working principle and beneficial effects of the above-mentioned technical solution are as follows: the first air pipe 10 is arranged at the front side of the heat dissipation net 2, hot air emitted from the heat dissipation net 2 enters into the first air pipe 10 and then flows into the second air pipe 11 and then is ejected from the nozzle 12 of the second air pipes 11, so that an ejected air can be sprayed to the upper surface of the industrial control computer body 1. A number of the second air pipes 11 is the same as a number of the intervals of the heat dissipation fins 3, and the nozzle 12 is directly faces one of the intervals. Using the hot air ejected from the nozzles 12, on the one hand, dust can be blown off from the upper surface of the industrial control computer body 1, and on the other hand, part of the dust attached to the surface of the heat dissipation fins 3 can also be blown off, so as to avoid dust accumulation and enable full contact of the surface of the heat dissipation fins 3 with outside air, thereby making full use of the emitted hot air, saving resource, and improving cleaning effect for the heat dissipation fins 3.

### Embodiment 5

On the basis of embodiment 1, as shown in FIG. 2, a heat dissipation fan 13 is provided in the industrial control computer body 1, and the heat dissipation fan 13 directly faces the heat dissipation net 2, and the heat dissipation fan 13 is fixedly connected to an inner wall of a rear side of the industrial control computer body 1 via connecting pole 14.

A working principle and a beneficial effect of the above-mentioned technical solution are as follows: the heat dissipation fan 13 is provided in the industrial control computer body 1, after the heat dissipation fan 13 is actuated, hot air inside the industrial control computer body 1 can be emitted from the heat dissipation network 2, so as to speed up heat dissipation of the industrial control computer body 1.

### Embodiment 6

On the basis of Embodiment 3, as shown in FIGS. 1 to 5, the second cleaning device includes:
a second motor 15, arranged on an outer wall of a left side of the industrial control computer body 1, wherein an output end of the second motor 15 is provided with a first gear 16, and the first gear 16 is an incomplete gear, and the output end of the second motor 15 is fixedly connected to the first gear 16;
a first fixing plate 17, arranged on a left side wall of the industrial control computer body 1, and a third through hole is formed in the first fixing plate 17;
a second fixing plate 18, arranged on the left side wall of the industrial control computer body 1, wherein the second fixing plate 18 is located in front of the first fixing plate 17, and a fourth through hole with a same size as the third through hole is formed in the second fixing plate 18;
a sliding plate 19, an end of the sliding plate 19 is slidably connected with the first fixing plate 17 via the third through hole, an another end of the sliding plate 19 is slidably connected with the second fixing plate 18 via the fourth through hole;
a rack 20, arranged on a left side of the sliding plate 19, wherein a side wall of the rack 20 is fixedly connected with a side wall of the sliding plate 19, an both an upper end and a lower end of the rack 20 have teeth, and a toothed position at the lower end of the rack 20 is intermittently meshed with the first gear 16, and the rack 20 slides back and forth between the first fixed plate 17 and the second fixed plate 18 along with the sliding plate 19;
a baffle 21, arranged at a front end of the sliding plate 19;
a first spring 22, being sleeved on the sliding plate 19, wherein an end of the first spring 22 is fixedly connected to a rear side wall of the baffle 21, and another end of the first spring 22 is fixedly connected to a front side wall of the second fixing plate 18;
a first rotating shaft 23, arranged on the left side wall of the industrial control computer body 1, wherein the first rotating shaft 23 is perpendicular to the left side wall of the industrial control computer body 1 and is rotatably connected to the left side wall of the industrial control computer body 1; the first rotating shaft 23 is located above the sliding plate 19, and an end, away from the industrial control computer body 1, of the first rotating shaft 23 is provided with a second gear 24, and the second gear 24 is fixedly connected to the first rotating shaft 23, and a tooth profile of the second gear 24 meshes with a toothed position at the upper end of the rack 20; and
a connecting rod 25, arranged at a periphery of the second gear 24, wherein an end of the connecting rod 25 is fixedly connected to an outer wall of the second gear 24, and another end of the connecting rod 25 is provided with a mounting plate 26, and the connecting rod 25 is hinged to a left side wall of the mounting plate 26, and a plurality of cleaning assemblies are arranged under the mounting plate 26, and the plurality of the cleaning assemblies are distributed between every two adjacent heat dissipation fins 3.

In some embodiments, each of the cleaning assemblies includes:
a second sliding block 27, arranged between two adjacent heat dissipation fins 3, wherein a left end and a right end of the second sliding block 27 are symmetrically provided with a third sliding block 28, a side, facing the second sliding block 27, of each of the heat dissipation fins 3 is provided with a sliding groove 29 matched with the third sliding block 28, and the third sliding block 28 is slidably connected with the sliding groove 29, and the second sliding block 27 slides back and forth along a side wall of each of the heat dissipation fins 3;
a mounting pole 30, arranged on a lower surface of the second sliding block 27, wherein an upper end of the mounting pole 30 is fixedly connected to the lower surface of the second sliding block 27, and an outer wall of the mounting pole 30 is provided with a plurality of second bristles 31, an end of the second bristles 31 is fixedly connected to an outer wall of the mounting pole 30, and another end of the second bristles 31 is in contact with an outer wall of each of the heat dissipation fins 3; and
a sleeve 32, arranged at an upper end of the second sliding block 27, wherein a lower end of the sleeve 32 is fixedly connected to the upper end of the second sliding block 27, and a second spring 33 is arranged in the sleeve 32, and an end of the second spring 33 is fixedly connected to an inner wall of the sleeve 32, and another end of the second spring 33 is provided with a sliding rod 34, and an end of the sliding rod 34 is slidably connected with the inner wall of the sleeve 32, and another end of the sliding rod 34 extends above the sleeve 32 and is fixedly connected to a lower surface of the mounting plate 26.

In other embodiments, a front side wall and a rear side wall of the industrial control computer body 1 are symmetrically provided with dust receiving assemblies, and each of the dust receiving assemblies includes:
a second dust receiving box 35, an end of the second dust receiving box 35 is provided with a first clamping plate 36, and another end of the second dust receiving box 35 is provided with a second clamping plate 37, wherein a second threaded hole is formed in the second clamping plate 37, and a right side wall of the first clamping plate 36 is in contact with the outer wall of the left side of the industrial control computer body 1; and
a second stud 38, being in threaded driving connection with the second clamping plate 37 through the second threaded hole, wherein the second stud 38 is perpendicular to the second clamping plate 37, and an end, close to a right side wall of the industrial control computer body 1, of the second stud 38 is provided with an anti-skid plate 39, and the anti-skid plate 39 is rotatably connected to an end of the second stud 38, and another end of the second stud 38 extends to a right side of the second clamping plate 37 and is provided with a knob 40, and the knob 40 is fixedly connected to the second stud 38.

A working principle and beneficial effects of the above-mentioned technical solution are as follows: before the second cleaning device is used, the dust receiving assembly can be installed firstly, wherein a right side wall of the first clamping plate 36 is in contact with the left side wall of the industrial control computer body 1, and then the second splint 37 is positioned on the right side of the industrial control computer body 1, turning the knob 40, and the turning of the knob 40 drives the second stud to rotate. The second stud drives the anti-skid plate 39 to approach the right side wall of the industrial control computer body 1 by means of threaded driving until the anti-skid plate 39 is in close contact with the right side wall of the industrial control computer body 1. At the moment, the second dust receiving box 35 is installed on the industrial control computer body 1. Then, when the heat dissipation fins 3 need to be cleaned up, the second motor 15 is actuated. The second motor 15 rotates counterclockwise to drive the first gear 16 to rotate counterclockwise. The first gear 16 is an incomplete gear, and the first gear 16 can intermittently mesh with the rack 20. When the first gear 16 meshes with the rack 20, the first gear 16 drives the rack 20 to move backwards, and the rack 20 drives the sliding plate 19 to slide backwards within a range between the first fixing plate 17 and the second fixing plate 18, and the baffle 21 moves backwards, thereby the first spring 22 is compressed; the rack 20 meshes with the second gear 24, and the rack 20 drives the second gear 24 to rotate clockwise; the second gear 24 thereby drives the connecting rod 25 to swing from back to front, and the connecting rod 25 drives the mounting plate 26 to move from back to front; the mounting plate 26 drives the sliding rod 34 to move from back to front, and the sliding rod 34 drives, by means of the sleeve 32, the second sliding block 27 to slide between two of the heat dissipation fins 3, and the third sliding block 28 slides in the sliding groove 29. At the same time, the sliding rod 34 slides in the sleeve 32, and the second spring 33 moves along with the movement of the sliding rod 34. When the second sliding block 27 slides, it drives the mounting pole 30 to move, so that the second bristles 31 provided on the outer wall of the mounting pole 30 can clean up the heat dissipation fins 3 and the upper surface of the industrial control computer body 1 from back to front. The dust cleaned up falls into the second dust receiving box 35 at the front side of the industrial control computer body 1. When the second sliding block 27 slides to the foremost position, meshing between the first gear 16 and the rack 20 ends, and then the sliding plate 19 drives the rack 20 to slide from back to front under the action of an elastic force of the first spring 22; the rack 20 drives the second gear 24 to rotate counterclockwise, and the connecting rod 25 starts to swing backwards, and the cleaning assemblies are driven by the mounting plate 26 to slide backwards, so that the second bristles 31 clean up the upper surface of the industrial control computer body 1 and the outer wall of one of the heat dissipation fins 3 from front to back. Finally, the dust cleaned up falls into the second dust receiving box 35 at a rear side of the of the industrial control computer body 1. By providing the second cleaning device, the back and forth reciprocation of the bristles 31 on the upper surface of the industrial control computer body 1 can be realized, and the back and forth reciprocation of the second bristles 31 can be utilized to complete the cleaning of the heat dissipation fins 3 and the upper surface of the industrial control computer body 1, which realizes quick cleaning of the heat dissipation fins 3, improves cleanliness of the heat dissipation fins 3 and the upper surface of the industrial control computer body 1, and improves the heat dissipation effect of the heat dissipation fins 3. Besides, the second cleaning device occupies less space so that installation of the industrial control computer body 1 will not be affected. The second cleaning device is used for completing dust cleaning of the heat dissipation fins 3, which improves the safety during cleaning, and avoids a scratch accident, and reduces the labor intensity of workers. The problem that gaps of heat dissipation fins are small and difficult to clean up is solved. At the same time, an automation degree of the industrial control computer body 1 is improved.

A cleaning method of a convenient cleaning apparatus for an industrial control computer according to some embodiments of the disclosure, using one of the above-mentioned convenient cleaning apparatus for an industrial control computer to clean up an industrial control computer, and the cleaning method includes the following steps.

In step 1, actuating the first motor 4, the first motor 4 rotates forwards to drive the first sliding block 6 to slide downwards along the guide rod 7, and the first sliding block 6 drives the first bristles 8 to clean an inner wall of the heat dissipation net 2 from top to bottom; when the first sliding block 6 moves to a preset lowest position, the first motor 4 reversely rotates to drive the first sliding block 6 to slide upwards along the guide rod 7, and the first sliding block 6 drives the first bristles 8 to clean the inner wall of the heat dissipation net 2 again from bottom to top; and when the first sliding block 6 moves to a preset highest position, the first motor 4 rotates forwards again, and repeating the above-mentioned operations.

In step 2, actuating the second motor 15, the second motor 15 rotates to drive the cleaning assemblies to slide back and forth on the upper surface of the industrial control computer body 1, and the second bristles 31 cleans a side wall of one of the heat dissipation fins 3 and the upper surface of the industrial control computer 1.

In step 3, after the heat dissipation net 2 is cleaned up, turning off the first motor 4; and when the heat dissipation fins 3 are cleaned up, turning off the second motor 15.

A working principle and beneficial effects of the above-mentioned technical solution are as follows: firstly, actuating the first motor 4, and the first motor 4 rotates forward to drive the first sliding block 6 to slide downwards along the guide rod 7, so that the first sliding block 6 drives the first bristles 8 to clean up the inner wall of the heat dissipation net 2 from top to bottom. When the first sliding block 6 moves to the preset lowest position, the first motor 4 rotates reversely to drive the first sliding block 6 to slide upwards along the guide rod 7, so that the first sliding block 6 drives the first bristles 8 to clean up the inner wall of the heat dissipation net 2 again from bottom to top. When the first sliding block 6 moves to the preset highest position, the first motor 4 rotates forward once again, and repeats the above-mentioned operations. Next, actuating the second motor 15, and the second motor 15 rotates to drive the cleaning assemblies to slide back and forth on the upper surface of the industrial control computer body 1. The second bristles 31 clean up the side walls of the heat dissipation fins 3 and the upper surface of the industrial control computer. When the heat dissipation net 2 is cleaned up, the first motor 4 is turned off; and when the heat dissipation fins 3 are cleaned up, the second motor 15 is turned off. A timing device is also provided in the industrial control computer body 1, and the timing device is electrically connected to the first motor 4 and the second motor 15. The timing device can turn on the motor 4 and the second motor 15 regularly, and turn off the first motor 4 and the second motor 15 after the first motor 4 and the second motor 15 work for a preset duration, which achieves automatic control. In this way, quick cleaning of the industrial control computer is automatically completed, labor intensity of workers is reduced, safety of cleaning is improved, and overall intelligent degree of the apparatus is improved.

Obviously, those skilled in the art may implement various modifications and variations to the disclosure without departing from the scope of the disclosure. As such, in case that these modifications and variations of the disclosure fall within the scopes of the claims of the disclosure and of equivalent technologies thereof, the disclosure also intends to include these modifications and variations.

1. A convenient cleaning apparatus for an industrial control computer, comprising: an industrial control computer body (1), a heat dissipation hole is formed in a front side wall of the industrial control computer body (1), and a heat dissipation net (2) is arranged in the heat dissipation hole; a first cleaning device is arranged inside the industrial control computer body (1), and the first cleaning device is configured to clean the heat dissipation net (2); a plurality of heat dissipation fins (3) are arranged on an outer wall of an upper end of the industrial control computer body (1); and a second cleaning device is arranged outside the industrial control computer body (1), and the second cleaning device is configured to clean the heat dissipation fins (3).

2. The convenient cleaning apparatus for an industrial control computer as claimed in claim 1, wherein the plurality of heat dissipation fins (3) are arranged at equal intervals, and the plurality of heat dissipation fins (3) are parallel to each other.

3. The convenient cleaning apparatus for an industrial control computer as claimed in claim 1, wherein the first cleaning device includes:
a first motor (4), arranged inside the industrial control computer body (1), and an upper end of the first motor (4) is fixedly connected to an inner wall of the upper end of the industrial control computer body (1), and the first motor (4) is a forward/reverse rotation motor;
a first screw rod (5), an end of the first screw rod (5) is fixedly connected to an output end of the first motor (4), and another end of the first screw rod (5) is rotatably connected to an inner wall of a lower end of the industrial control computer body (1);
a first sliding block (6), arranged on the first screw rod (5), and a threaded hole is formed in the first sliding block (6) in a penetrating manner, and the first sliding block (6) is in threaded driving connection with the first screw rod (5) via the threaded hole, and a first through hole is further formed in the first sliding block (6), and the first through hole passes through an upper surface and a lower surface of the first sliding block (6);
a guide rod (7), arranged between the first motor (4) and the heat dissipation net (2), and an upper end and a lower end of the guide rod (7) are fixedly connected to inner walls of an upper side and a lower side of the industrial control computer body (1) respectively, and the guide rod (7) is slidably connected with an inner wall of the first through hole, and the first sliding block (6) slides up and down along the guide rod (7);
a first bristles (8), arranged on a side of the first sliding block (6) facing the heat dissipation net (2), and an end of the first bristles (8) is fixedly connected to a side wall of the first sliding block (6), and another end of the first bristles (8) is in contact with an inner side wall of the heat dissipation net (2).

4. The convenient cleaning apparatus for an industrial control computer as claimed in claim 3, wherein a second through hole is arranged below the heat dissipation net (2), and a first dust receiving box (9) is arranged in the second through hole, and the first dust receiving box (9) is configured in a drawer shape, and the first dust receiving box (9) is slidably connected with an inner wall of the second through hole, and an upper end of the first dust receiving box (9) is provided with an opening.

5. The convenient cleaning apparatus for an industrial control computer as claimed in claim 1, wherein a first air pipe (10) is arranged at a front side of the heat dissipation net (2), and an end of the first air pipe (10) is fixedly connected to a front side wall of the industrial control computer body (1), and the first air pipe (10) is in communication with the heat dissipation hole, and an upper end of the first air pipe (10) is provided with a plurality of second air pipes (11), and the second air pipes (11) are configured in L shapes; an end of one of the second air pipes (11) is in communication with an upper end of the first air pipe (10), and another end of one of the second air pipes (11) is provided with a nozzle (12), and an outlet of the nozzle (12) faces an upper surface of the industrial control computer body (1); and a plurality of intervals are formed between every two adjacent heat dissipation fins (3), and the plurality of intervals are in one-to-one correspondence with the plurality of the second air pipes (11).

6. The convenient cleaning apparatus for an industrial control computer as claimed in claim 1, wherein a heat dissipation fan (13) is arranged in the industrial control computer body (1), and the heat dissipation fan (13) directly faces the heat dissipation net (2) and the heat dissipation fan (13) is fixedly connected to an inner wall of a rear side of the industrial control computer body (1) via a connecting pole (14).

7. The convenient cleaning apparatus for an industrial control computer as claimed in claim 3, wherein the second cleaning device includes:
a second motor (15), arranged on an outer wall of a left side of the industrial control computer body (1), and an output end of the second motor (15) is provided with a first gear (16), and the first gear (16) is an incomplete gear, and the output end of the second motor (15) is fixedly connected to the first gear (16);
a first fixing plate (17), arranged on a left side wall of the industrial control computer body (1), and a third through hole is formed in the first fixing plate (17);
a second fixing plate (18), arranged on the left side wall of the industrial control computer body (1), and the second fixing plate (18) is located in front of the first fixing plate (17), and a fourth through hole with a same size as the third through hole is formed in the second fixing plate (18);
a sliding plate (19), an end of the sliding plate (19) is slidably connected with the first fixing plate (17) via the third through hole, and another end of the sliding plate (19) is slidably connected with the second fixing plate (18) via the fourth through hole;
a rack (20), arranged on a left side of the sliding plate (19), and a side wall of the rack (20) is fixedly connected with a side wall of the sliding plate (19), and both an upper end and a lower end of the rack (20) have teeth, and a toothed position at the lower end of the rack (20) is intermittently meshed with the first gear (16), and the rack 20 slides back and forth between the first fixed plate (17) and the second fixed plate (18) along with the sliding plate (19);
a baffle (21), arranged at a front end of the sliding plate (19);
a first spring (22), being sleeved on the sliding plate (19), and an end of the first spring 22 is fixedly connected to a rear side wall of the baffle (21), and another end of the first spring (22) is fixedly connected to a front side wall of the second fixing plate (18);
a first rotating shaft (23), arranged on the left side wall of the industrial control computer body (1), and the first rotating shaft (23) is perpendicular to the left side wall of the industrial control computer body (1) and is rotatably connected to the left side wall of the industrial control computer body (1), and the first rotating shaft (23) is located above the sliding plate (19), and an end, away from the industrial control computer body (1), of the first rotating shaft (23) is provided with a second gear 24, and the second gear 24 is fixedly connected to the first rotating shaft (23), and a tooth profile of the second gear 24 meshes with a toothed position at the upper end of the rack (20); and
a connecting pole (25), arranged at a periphery of the second gear (24), and an end of the connecting pole (25) is fixedly connected to an outer wall of the second gear (24), and another end of the connecting pole (25) is provided with a mounting plate (26), and the connecting pole (25) is hinged to a left side wall of the mounting plate (26), and a plurality of cleaning assemblies are arranged under the mounting plate (26), and the plurality of the cleaning assemblies are distributed between every two adjacent heat dissipation fins (3).

8. The convenient cleaning apparatus for an industrial control computer as claimed in claim 7, wherein each of the cleaning assemblies includes:
a second sliding block (27), arranged between two adjacent heat dissipation fins (3), and a left end and a right end of the second sliding block (27) are symmetrically provided with a third sliding block (28), a side, facing the second sliding block (27), of each of the heat dissipation fins (3) is provided with a sliding groove (29) matched with the third sliding block (28), and the third sliding block (28) is slidably connected with the sliding groove (29), and the second sliding block (27) slides back and forth along a side wall of each of the heat dissipation fins (3);
a mounting pole (30), arranged on a lower surface of the second sliding block (27), and an upper end of the mounting pole (30) is fixedly connected to the lower surface of the second sliding block (27), and an outer wall of the mounting pole (30) is provided with a plurality of second bristles (31), and an end of the second bristles (31) is fixedly connected to an outer wall of the mounting pole (30), and another end of the second bristles 31 is in contact with an outer wall of each of the heat dissipation fins (3); and
a sleeve (32), arranged at an upper end of the second sliding block (27), and a lower end of the sleeve (32) is fixedly connected to the upper end of the second sliding block (27), and a second spring (33) is arranged in the sleeve (32), and an end of the second spring (33) is fixedly connected to an inner wall of the sleeve (32), and another end of the second spring (33) is provided with a sliding rod (34), and an end of the sliding rod (34) is slidably connected with the inner wall of the sleeve (32), and another end of the sliding rod (34) extends above the sleeve (32) and is fixedly connected to a lower surface of the mounting plate (26).

9. The convenient cleaning apparatus for an industrial control computer as claimed in claim 8, wherein a front side wall and a rear side wall of the industrial control computer body (1) are symmetrically provided with dust receiving assemblies, and each of the dust receiving assemblies includes:
a second dust receiving box (35), an end of the second dust receiving box (35) is provided with a first clamping plate (36), and another end of the second dust receiving box (35) is provided with a second clamping plate (37), and a second threaded hole is formed in the second clamping plate (37), and a right side wall of the first clamping plate (36) is in contact with the outer wall of the left side of the industrial control computer body (1); and
a second stud (38), being in threaded driving connection with the second clamping plate (37) via the second threaded hole, and the second stud (38) is perpendicular to the second clamping plate (37), and an end, close to a right side wall of the industrial control computer body (1), of the second stud (38) is provided with an anti-skid plate (39), and the anti-skid plate (39) is rotatably connected to an end of the second stud (38), and another end of the second stud (38) extends to a right side of the second clamping plate (37) and is provided with a knob (40), and the knob (40) is fixedly connected to the second stud (38).

10. A cleaning method of a convenient cleaning apparatus for an industrial control computer, using the convenient cleaning apparatus for an industrial control computer as claimed in claim 9 to clean an industrial control computer, wherein the cleaning method comprises the following steps:
step 1, actuating the first motor (4), the first motor (4) rotates forwards to drive the first sliding block (6) to slide downwards along the guide rod (7), and the first sliding block (6) drives the first bristles (8) to clean an inner wall of the heat dissipation net (2) from top to bottom; when the first sliding block (6) moves to a preset lowest position, the first motor (4) reversely rotates to drive the first sliding block (6) to slide upwards along the guide rod (7), and the first sliding block (6) drives the first bristles (8) to clean the inner wall of the heat dissipation net (2) again from bottom to top; and when the first sliding block (6) moves to a preset highest position, the first motor (4) rotates forwards again; repeating the above-mentioned operations;
step 2, actuating the second motor (15), the second motor (15) rotates to drive the cleaning assemblies to slide back and forth on the upper surface of the industrial control computer body (1), and the second bristles (31) cleans a side wall of one of the heat dissipation fins (3) and the upper surface of the industrial control computer (1); and
step 3, after the heat dissipation net (2) is cleaned up, turning off the first motor (4); and when the heat dissipation fins (3) are cleaned up, turning off the second motor (15).
